(19) United States
(12) Patent Application Publication
(10) Pub. No.: US 2025/0293217 A1
(43) Pub. Date: Sep. 18, 2025

(54) EMBEDDED PACKAGE WITH STACKED SEMICONDUCTOR DIES

(71) Applicant: Infineon Technologies AG, Neubiberg (DE)

(72) Inventors: Toni Salminen, München (DE); Eung San Cho, Torrance, CA (US); Jörn Kampmeier, Obertraubling (DE)

(21) Appl. No.: 18/603,481

(22) Filed: Mar. 13, 2024

(51) Int. Cl. H01L 25/16; H01L 21/48; H01L 23/00; H01L 23/31; H01L 23/498; H01L 25/00

(52) U.S. Cl. CPC H01L 25/16; H01L 21/4803; H01L 23/3121; H01L 23/49838; H01L 24/08; H01L 24/32; H01L 24/83; H01L 25/50; H01L 2224/08225; H01L 2224/32145; H01L 2224/83894; H01L 2924/1431; H01L 2924/1815

(57) ABSTRACT

A method of producing a semiconductor package includes providing a first semiconductor die and a second semiconductor die; providing a carrier frame comprising a cavity; mounting the second semiconductor die on the first semiconductor die, thereby forming a chip stack; and forming one or more laminate dielectric layers within the cavity that encapsulate at least one of the second semiconductor die and the first semiconductor die.

### BACKGROUND

Semiconductor packages are designed to protect semiconductor dies from the exterior environment and provide external electrical accessibility to the semiconductor dies. A variety of different semiconductor packaging solutions exist. One semiconductor packaging solution involves a lamination technique whereby the semiconductor dies are embedded within one or more lamination layers that form the encapsulant. The lamination technique may involve successively stacking lamination layers on top of one another. In some applications, it is desirable or necessary to provide two or more semiconductor dies together in a single package. One example of a multi-die package is a power package that comprises two or more power transistor dies that are configured as a power conversion circuit, e.g., half-bridge. Another example of a multi-die package is a sensor package that includes an IC (integrated circuit) together with a sensor device. While it is desirable to package these multi-die packages using lamination techniques, current solutions present challenges with respect to space efficiency and process complexity.

### SUMMARY

A method of producing a semiconductor package is disclosed. According to an embodiment, the method comprises: providing a first semiconductor die and a second semiconductor die; providing a carrier frame comprising a cavity; mounting the second semiconductor die on the first semiconductor die, thereby forming a chip stack; and forming one or more laminate dielectric layers within the cavity that encapsulate at least one of the second semiconductor die and the first semiconductor die.

According to another embodiment, the method comprises: providing a first power transistor die and a second power transistor die, the first and second power transistor dies each comprising a first load terminal disposed on a main surface and a second load terminal disposed on a rear surface opposite from the main surface; providing a carrier frame comprising a cavity; mounting the second semiconductor die on the first power transistor die such that the first load terminal of the first power transistor die directly interfaces with and is electrically connected to the second load terminal of the second semiconductor die, thereby forming a chip stack; arranging the chip stack within the cavity; and forming one or more laminate dielectric layers within the cavity that encapsulate the chip stack.

A semiconductor package is disclosed. According to an embodiment, the semiconductor package comprises: a carrier frame comprising a cavity; a chip stack comprising a second semiconductor die mounted directly on a first semiconductor die; and one or more laminate dielectric layers formed within the cavity, wherein at least one of the second semiconductor die and the first semiconductor die is arranged within the cavity and is encapsulated by the one or more laminate dielectric layers.

According to another embodiment, the semiconductor package comprises: a carrier frame comprising a cavity; a chip stack arranged within the cavity and comprising a first power transistor die and a second power transistor die, the first and second power transistor dies each comprising a first load terminal disposed on a main surface and a second load terminal disposed on a rear surface opposite from the main surface; and one or more laminate dielectric layers formed within the cavity, wherein the second semiconductor die is mounted on the first power transistor die such that the first load terminal of the first power transistor die directly interfaces with and is electrically connected to the second load terminal of the second semiconductor die, and wherein the chip stack is encapsulated by the one or more laminate dielectric layers.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a semiconductor package, according to an embodiment.

FIG. 2, which includes FIGS. 2A-2G, illustrates selected steps in a method of forming a semiconductor package, according to an embodiment.

FIG. 3, which includes FIGS. 3A-3I, illustrates selected steps in a method of forming a semiconductor package, according to an embodiment.

FIG. 4, which includes FIGS. 4A-4F, illustrates selected steps in a method of forming a semiconductor package, according to an embodiment.

FIG. 5, which includes FIGS. 5A-5B, illustrates a semiconductor package, according to embodiments.

FIG. 6, which includes FIGS. 6A-6B, illustrates selected steps in a method of forming a semiconductor package, according to an embodiment.

### DETAILED DESCRIPTION

A semiconductor package with an advantageous multi-die chip stack configuration and corresponding methods of forming the semiconductor package with the advantageous multi-die chip stack configuration are described herein. The semiconductor package is produced by a lamination technique that encapsulates the multi-die chip stack within one or more laminate dielectric layers. According to the technique, a carrier frame comprising a cavity is provided on a temporary carrier and a chip stack comprising first and second semiconductor dies is arranged within the cavity. The chip stack is encapsulated by laminate dielectric layers that are formed within the cavity and around the chip stack. In some embodiments, the chip stack is created before performing any lamination step. In other embodiments, the chip stack is created after embedding one of the semiconductor dies within one of the laminate dielectric layers. In each embodiment, the chip stack is created without providing any of the laminate dielectric layers in between the first semiconductor die and the second semiconductor die. In some embodiments, an adhesive material that differs from the material of the laminate dielectric layers is provided between the first semiconductor die and the second semiconductor die. In other embodiments, the first semiconductor die and the second semiconductor die are affixed directly to one another. Package terminals are formed over the laminate dielectric layers with short, direct connections to the semiconductor dies from the chip stack. The chip stacking technique advantageously provides a multi-die chip stack within one cavity of a carrier frame, thereby improving space-efficiency and allowing for low-cost manufacturing.

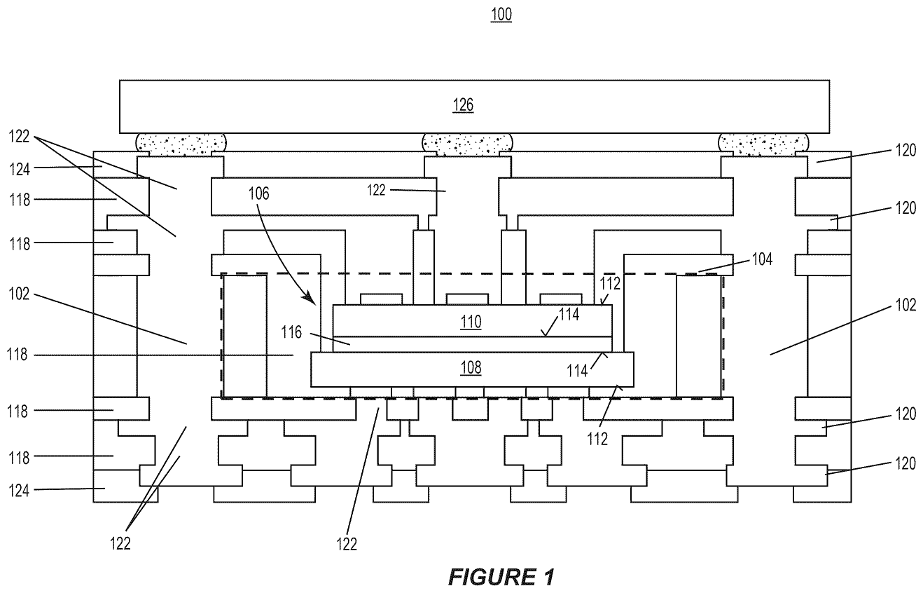

Referring to FIG. 1, a semiconductor package 100 comprises a carrier frame 102. The carrier frame 102 comprises an electrically conductive metal such as copper, aluminium, nickel, silver, palladium, gold, etc., and alloys thereof. The carrier frame 102 may include a core metal region that is formed form any of the above-mentioned metals and may further include one or more coatings formed on the core metal region that are formed from a different metal which may include any of the above-mentioned metals. These coatings may serve a variety of purposes, e.g., protection, adhesion, anti-corrosion, etc. The carrier frame 102 comprises a cavity 104. The cavity 104 is an interior volume that is within a perimeter defined by planes of the interior walls of the carrier frame 102. The carrier frame 102 may be a continuous ring-shaped structure that completely surrounds the cavity 104. Alternatively, the carrier frame 102 may include interruptions around the cavity 104. For example, from a plan-view perspective of the carrier frame 102, the interior walls of the carrier frame 102 may extend along planes that form an enclosed shape, e.g., a rectangle, and there may be gaps between sections of the carrier frame 102. In this case, the interior walls of the carrier frame 102 may define at least 50% of an overall perimeter of the cavity 104, with the remaining perimeter being defined by the planes that are coplanar with the interior walls of the carrier frame 102 and extend between the sections of the carrier frame 102.

The semiconductor package 100 comprises a chip stack 106 that is formed from a first semiconductor die 108 and a second semiconductor die 110 mounted on the first semiconductor die 108. Generally speaking, the first and second semiconductor dies 108, 110 can have a variety of different device configurations. According to one embodiment, the first and second semiconductor dies 108, 110 are each configured as integrated circuits, e.g., silicon-based logic devices. The first and second semiconductor dies 108, 110 each comprise a main surface 112 comprising one or more terminals disposed thereon and a rear surface 114 opposite from the main surface 112. In the case of a lateral device, the rear surface 114 of the semiconductor dies may be an electrically inactive surface that is devoid of terminals. In the case of a vertical device, the rear surface 114 of the semiconductor dies may comprise one or more terminals. In the chip stack 106 according to the embodiment of FIG. 1, the first and second semiconductor dies 108, 110 are mounted in arrangement whereby the terminals of each die face away from one another. The main surface 112 of the first semiconductor die 108 corresponds to a downward-facing surface, and the main surface 112 of the second semiconductor die 110 corresponds to an upward-facing surface.

The semiconductor package 100 is configured such that at least one of the first semiconductor die 108 and the second semiconductor die 110 is arranged within the cavity 104. That is, at least one of the first semiconductor die 108 and the second semiconductor die 110 is completely contained within the interior volume defined by the planes of the interior walls and upper and lower surfaces of the carrier frame 102.

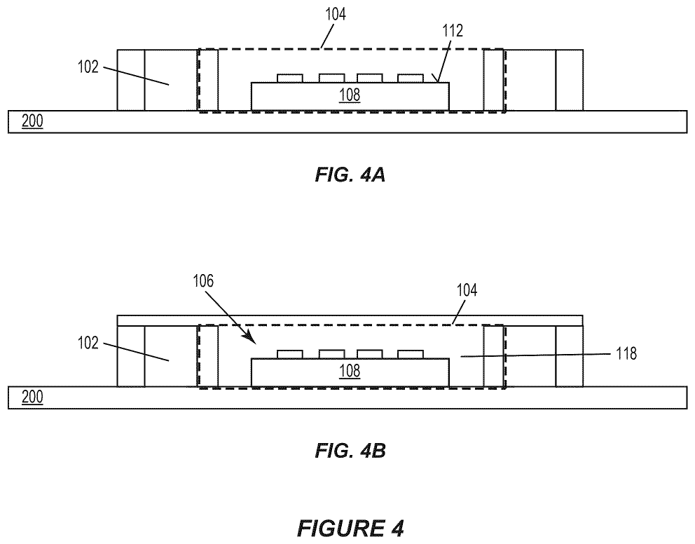

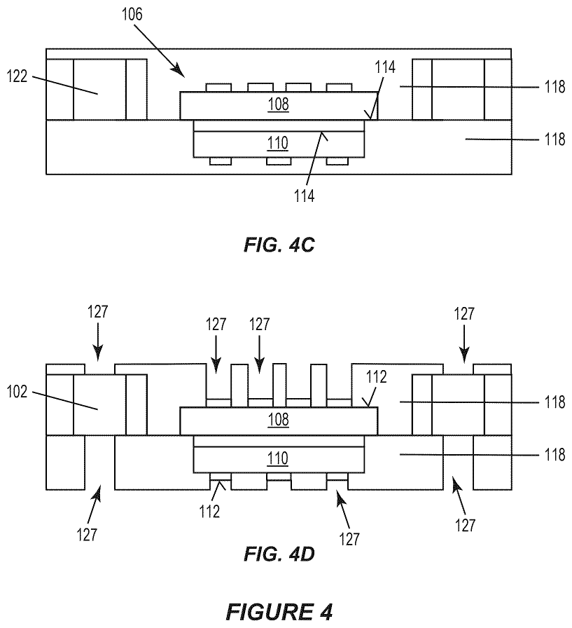

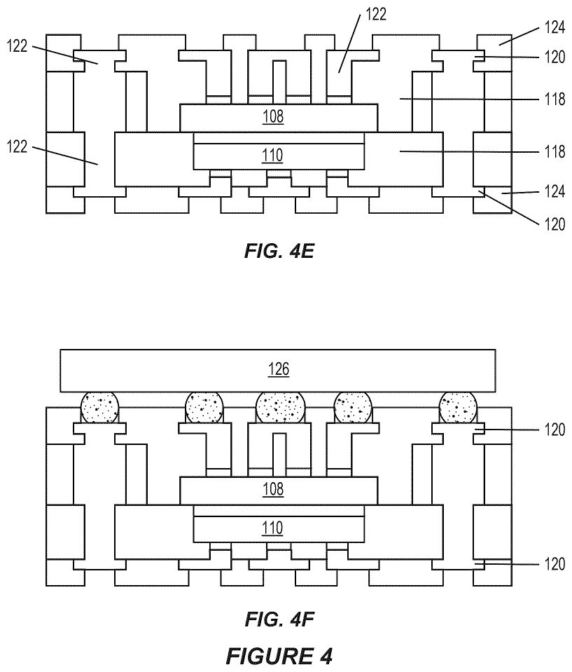

In the depicted embodiment, both of the first and second semiconductor dies 108, 110 are arranged within the cavity 104, i.e., the chip stack 106 is arranged completely within the cavity 104. In other embodiments, at least one of the first semiconductor die 108 and the second semiconductor die 110 may be at least partially disposed above or below the upper and lower planes of the carrier frame 102, e.g., as shown in the embodiment of FIG. 4 as will be described in further detail below.

According to an embodiment, the chip stack 106 comprises an attachment material 116 applied between the first semiconductor die 108 and the second semiconductor die 110. The attachment material 116 may be an electrically insulating material with adhesive properties, e.g., die attach tape, glue, etc. Alternatively, the attachment material 116 may be an electrically conductive material with adhesive properties, e.g., solder, sinter, etc. As explained above, in the embodiment of FIG. 1, the chip stack 106 is arranged with the main surface 112 of each die facing away from one another and with the rear surface 114 of each die facing one another. The attachment material 116 forms a direct interface between the rear surface 114 of the first semiconductor die 108 and the rear surface 114 of the second semiconductor die 110. As the rear surface 114 of each of the first and second semiconductor dies 108, 110 is electrically inactive, i.e., does not comprise terminals, the attachment material 116 can be electrically insulating or electrically conductive. The attachment material 116 is a material that is locally applied between the first semiconductor die 108 and the second semiconductor die 110. The attachment material 116 has a different composition the laminate dielectric layers that are used to encapsulate the chip stack 106. That is, the chip stack 106 is created without forming one or more layers of laminate material (to be discussed below) in between the first semiconductor die 108 and the second semiconductor die 110. In this way, the chip stack 106 has a compact vertical displacement, and can be provided within the cavity 104 of a single carrier frame 102 and laminated according to the techniques described below.

The semiconductor package 100 comprises a plurality of laminate dielectric layers 118. The laminate dielectric layers 118 are electrically insulating layers that are formed according to a lamination technique, examples of which will be described in further detail below. Examples of electrically insulating materials that the laminate dielectric layers 118 may be formed from or comprise include pre-preg material such as FR-4, FR-5, CEM-4 and resin material such as bismaleimide trazine (BT) resin.

The semiconductor package 100 is configured such that one or more of the laminate dielectric layers 118 are formed within the cavity 104. The laminate dielectric layers 118 that are formed within the cavity 104 encapsulate at least one of the second semiconductor die 110 and the first semiconductor die 108. Moreover, the complete chip stack 106 is encapsulated by one or more of the laminate dielectric layers 118 that are formed within or outside of the cavity 104.

In the depicted embodiment, the semiconductor package 100 comprises a first one of the laminate dielectric layers 118 formed within the cavity 104 and a second one of the laminate dielectric layers 118 formed within the cavity 104, with a first one of the laminate dielectric layers 118 encapsulating the first semiconductor die 108, and a second one of the laminate dielectric layers 118 encapsulating the second semiconductor die 110. Together, the first one of the laminate dielectric layers 118 and the second one of the laminate dielectric layers 118 collectively form an encapsulant around the chip stack 106. The depicted embodiment additionally comprises third, fourth and fifth ones of the laminate dielectric layers 118 formed outside of the cavity 104. The third, fourth and fifth ones of the laminate dielectric layers 118 are configured as interlayer dielectrics that facilitate routing of the electrical interconnects.

The semiconductor package 100 further comprises a plurality of metallization layers 120. The metallization layers 120 may each comprise electrically conductive metals such as copper (Cu), aluminium (AI), nickel (Ni), silver (Ag), palladium (Pd) gold (Au), etc., and alloys or combinations thereof. The metallization layers 120 may be formed into conductive tracks that form electrical routings. Additionally, the metallization layers 120 form externally accessible bond pads that form points of electrical accessibility to the first and second semiconductor dies 108, 110. In the depicted embodiment, the semiconductor package 100 comprises four of the metallization layers 120, with two outer ones of the metallization layers 120 being structured to form externally accessible bond pads, and two interior ones of the of the metallization layers 120 being patterned into conductive tracks that may form electrical routings.

The semiconductor package 100 further comprises conductive vias 122 that extend through one or more of the laminate dielectric layers 118. These conductive vias 122 provide electrical interconnect between two of the metallization layers 120 or one of the metallization layers 120 and one of the semiconductor dies. The conductive vias 122 may comprise electrically conductive metals such as copper, aluminium, tungsten, nickel, etc., and alloys or combinations thereof. The conductive vias 122 may be formed in trenches that are formed in the laminate dielectric layers 118. Additionally, the carrier frame 102 itself may be configured as a vertical conductive via. For example, in the depicted embodiment, the carrier frame 102 is contacted at upper and lower sides by conductive vias 122 and is configured as a complete vertical through-via that extends through the semiconductor package 100.

The semiconductor package 100 further comprises solder resist layers 124 that are formed on the outermost surfaces of the laminate dielectric layers 118 in between the bond pads. The solder resist may comprise lacquer, epoxy, liquid photoimageable solder mask, dry-film photoimageable solder mask, etc.

The package of FIG. 1 illustrates just one example of a semiconductor package 100 that includes a chip stack 106 embedded within one or more laminate dielectric layers 118. More generally, embodiments of the semiconductor package 100 disclosed herein may include any number of laminate dielectric layers 118, e.g., two, three, four, five, six, etc. and may include any number of metallization layers 120, e.g., two, three, four, five, six, etc.

In the depicted embodiment, the semiconductor package 100 additionally comprises a third semiconductor die 126 mounted outside of the laminate dielectric layers 118. The third semiconductor die 126 is mounted in a flip-chip configuration, with the terminals of the third semiconductor die 126 facing and electrically connected with bond pads of the semiconductor package 100. A conductive attachment material, e.g., solder, is provided between the third semiconductor die 126 and bond pads in the outermost metallization layer 120. Generally speaking, the third semiconductor die 126 can be any type of device. According to an embodiment, the third semiconductor die 126 is configured as a sensor device, e.g., a device configured to detect audio signals, mechanical pressure, temperature, etc. In this case, the first and second semiconductor dies 108, 110 may be configured to receive/interpret signals from the third semiconductor die 126 and/or send control signals to the third semiconductor die 126. Electrical interconnections between the third semiconductor die 126 and the first and second semiconductor dies 108, 110 may be provided by the metallization layers 120 and conductive vias 122.

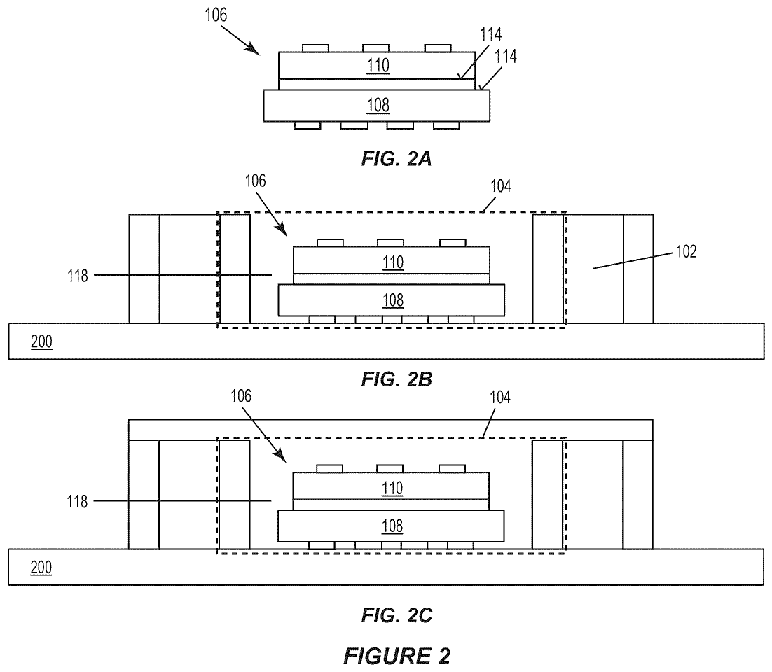

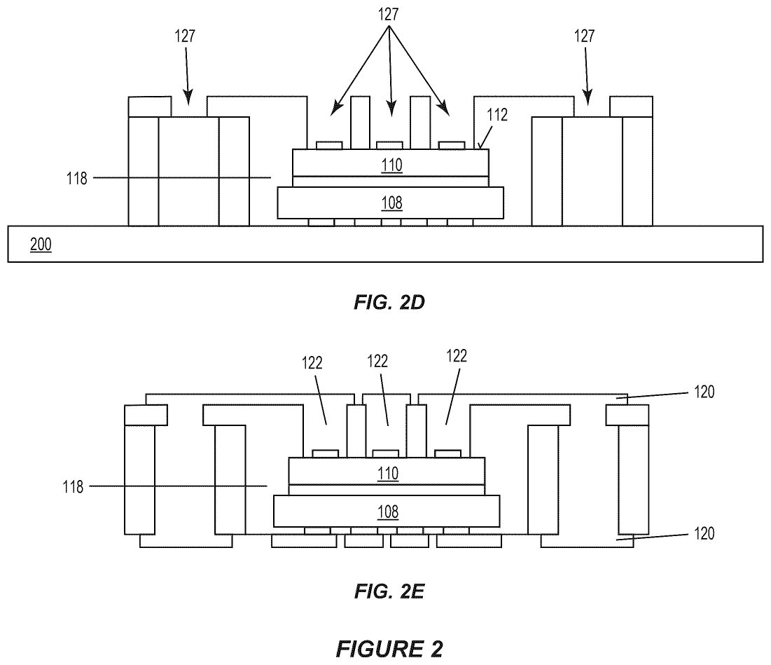

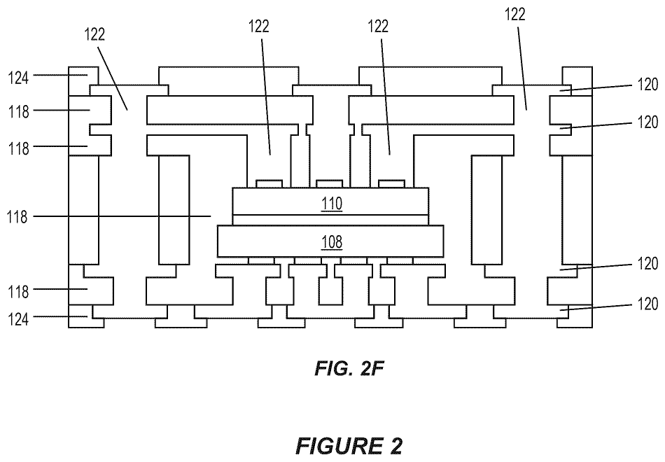

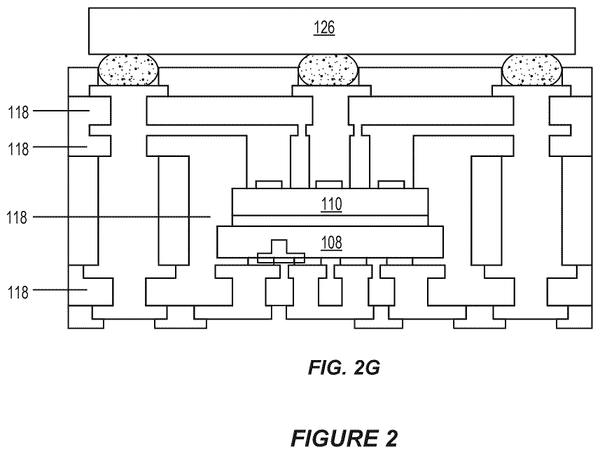

Referring to FIG. 2, a method for forming the semiconductor package 100 is shown, according to an embodiment. In this example, both of the second semiconductor die 110 and the first semiconductor die 108 are encapsulated by a first one of the laminate dielectric layers 118.

Referring to FIG. 2A, the chip stack 106 is formed by mounting the second semiconductor die 110 on the first semiconductor die 108. The chip stack 106 is created by directly adhering the rear surface 114 of the first semiconductor die 108 with the rear surface 114 of the second semiconductor die 110 using the attachment material 116. In the embodiment of FIG. 2, the second semiconductor die 110 is mounted on the first semiconductor die 108 before forming any of the dielectric layers that are formed within the cavity 104.

Referring to FIG. 2B, the carrier frame 102 is arranged on a temporary carrier 200. The temporary carrier 200 may comprise a rigid panel with a releasable tape, such as a polycarbonate tape, for example. As shown, the carrier frame 102 may be provided with a core metal structure and an additional region of electrically insulating material, e.g., resin material such as bismaleimide trazine (BT) resin surrounding the metal structure of the carrier frame 102. In other embodiments, the additional region of electrically insulating material may be omitted.

The chip stack 106 is arranged on the temporary carrier 200 within the cavity 104. The chip stack 106 may be created before arranging it on the temporary carrier 200. Alternatively, the chip stack 106 may be created by placing the first semiconductor die 108 on the temporary carrier 200 and mounting the second semiconductor die 110 thereon. The carrier frame 102 may be configured such that the vertical height of the carrier frame 102 is at least as great as the vertical height of the chip stack 106, i.e., the combined vertical displacement of the first and second semiconductor dies 108, 110 when mounted on one another. In this way, the volume of the cavity 104 is sufficiently large to accommodate the complete chip stack 106 arranged within it.

Referring to FIG. 2C, a lamination process is performed. In the depicted embodiment, the lamination process comprises forming a first one of the laminate dielectric layers 118 that fills the cavity 104 and encapsulates the first semiconductor die 108 and the second semiconductor die 110. As a result, the chip stack 106 is encapsulated. As shown, the first one of the laminate dielectric layers 118 may also cover an upper side of the carrier frame 102.

Referring to FIG. 2D, openings 127 are formed in the first one of the laminate dielectric layers 118. The openings 127 expose terminals from the main surface 112 of the second semiconductor die 110. Additionally, the openings 127 expose an upper surface of the carrier frame 102. The openings 127 may be created by an etching process, for example.

Referring to FIG. 2E, the conductive vias 122 are formed in the openings 127. This may be done by a metal deposition process, for example. Additionally, two of the metallization layers 120 are formed on the outer surfaces of the laminate dielectric layer 118. This may be done by a plating technique, for example. Alternatively, the metallization layers 120 can be a pre-patterned layer that is bonded to the laminate dielectric layers 118. Both sides of the package assembly may be metallized by flipping the package assembly upside on the temporary carrier 200 (not shown in FIG. 2E) or by placing the package assembly on a new temporary carrier.

Referring to FIG. 2F, second and third ones of the laminate dielectric layers 118 are formed over the interior metallization layers 120. Subsequently, openings 127 are formed in the second and third ones of the laminate dielectric layers 118, and conductive vias 122 are formed in these openings 127 in a similar manner as described above. Subsequently, two outer ones of the metallization layers 120 are provided on third and fourth ones of the laminate dielectric layers 118 and form externally accessible bond pads. Subsequently, solder resist layers 124 are formed on the outermost surfaces of the laminate dielectric layers 118.

Referring to FIG. 2G, the third semiconductor die 126 is mounted on the bond pads formed by one of the outermost metallization layers 120. As shown, the third semiconductor die 126 may be mounted in a flip-chip configuration wherein solder balls are provided between a main surface of the third semiconductor die 126 and the bond pads. Alternatively, the third semiconductor die 126 may be mounted according to other techniques, e.g., wire bonding, SMD (surface mount device), etc.

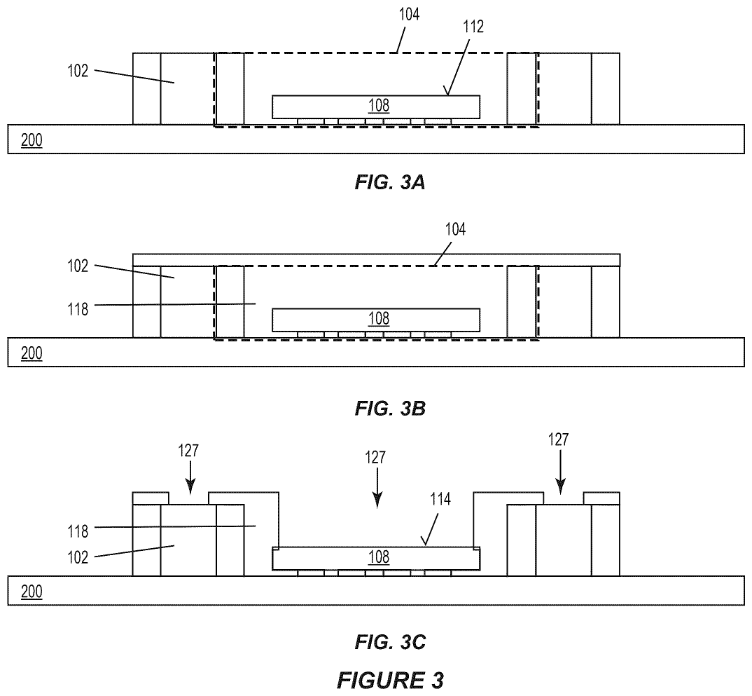

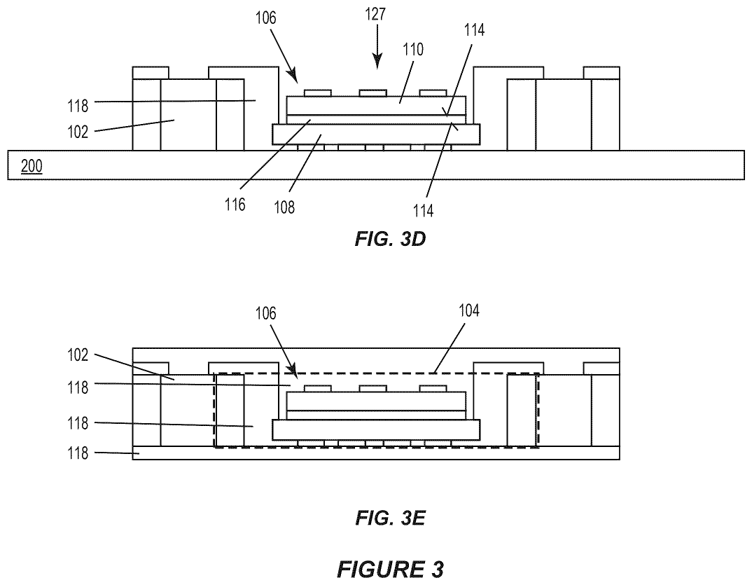

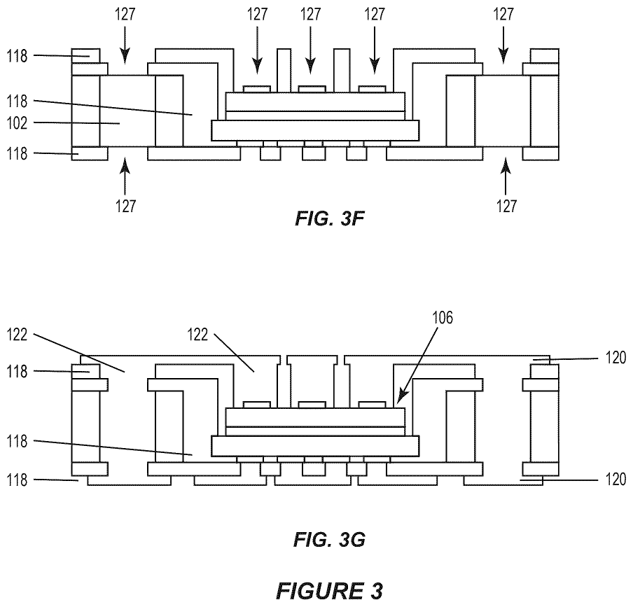

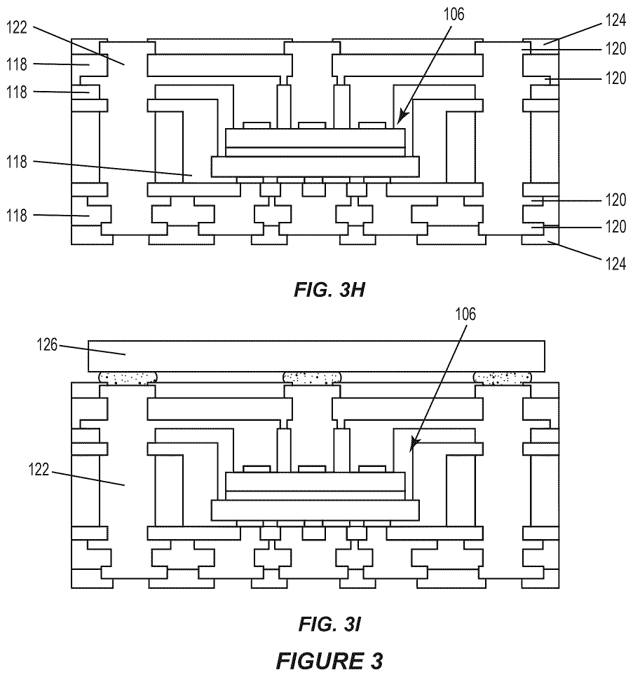

Referring to FIG. 3, a method for forming a semiconductor package 100 is shown, according to another embodiment. In this embodiment, the first semiconductor die 108 is encapsulated by a first one of the laminate dielectric layers 118, and the second semiconductor die 110 is encapsulated by a second one of the laminate dielectric layers 118 that is formed after arranging the first semiconductor die 108 within the cavity 104 and forming the first one of the laminate dielectric layers 118.

Referring to FIG. 3A, the carrier frame 102 is arranged on a temporary carrier 200. Subsequently, the first semiconductor die 108 is arranged on the temporary carrier 200 within the cavity 104. The first semiconductor die 108 is arranged with the main surface 112 of the first semiconductor die 108, which comprises terminals disposed thereon, facing the temporary carrier 200.

Referring to FIG. 3B, a lamination process is performed. In the depicted embodiment, the lamination process comprises forming a first one of the laminate dielectric layers 118 that fills the cavity 104 and encapsulates first semiconductor die 108. Thus, in this embodiment, the first one of the laminate dielectric layers 118 is formed within the cavity 104 before mounting the second semiconductor die 110 on the first semiconductor die 108. As shown, the first one of the laminate dielectric layers 118 may also cover an upper side of the carrier frame 102.

Referring to FIG. 3C, openings 127 are formed in the first one of the laminate dielectric layers 118. These openings 127 include a main opening that exposes the rear surface 114 of the first semiconductor die 108. These openings 127 additionally include openings 127 that expose an upper surface of the carrier frame 102. The openings 127 may be created by an etching process, for example.

Referring to FIG. 3D, the second semiconductor die 110 is mounted on the first semiconductor die 108, thereby forming a chip stack 106. The second semiconductor die 110 is arranged within the main opening 126 and the rear surface 114 of the second semiconductor die 110 is adhered to the rear surface 114 of first semiconductor die 108 using the attachment material 116 in a similar manner as described above.

Referring to FIG. 3E, the lamination process is continued by forming a second one of the laminate dielectric layers 118. The second one of the laminate dielectric layers 118 fills the cavity 104 and encapsulates the second semiconductor die 110. Thus, the chip stack 106 comprising the first semiconductor die 108 and the second semiconductor is collectively encapsulated by the first and second ones of the laminate dielectric layers 118. As shown, the second one of the laminate dielectric layers 118 may be formed to completely cover the upper side of the carrier frame 102. Additionally, a third one of the laminate dielectric layers 118 may be formed on an opposite side of the assembly that covers the main surface 112 of the first semiconductor die 108 and the lower side of the carrier frame 102.

Referring to FIG. 3F, openings 127 are formed in the second one of the laminate dielectric layers 118 and in the third one of the laminate dielectric layers 118. The openings 127 expose terminals from the main surface 112 of the second semiconductor die 110 and from the main surface 112 of the first semiconductor die 108. Additionally, the openings 127 expose upper and lower surfaces of the carrier frame 102. The openings 127 may be created by an etching process, for example.

Referring to FIG. 3G, the conductive vias 122 are formed in the openings 127. This may be done by a metal deposition process, for example. Additionally, two of the metallization layers 120 are formed on the outer surfaces of the laminate dielectric layers 118. This may be done by a plating technique, for example. Alternatively, the metallization layers 120 can be a pre-patterned layer that is bonded to the laminate dielectric layers 118. Both sides of the package assembly may be metallized by flipping the package assembly upside on the temporary carrier 200 or by placing the package assembly on a new temporary carrier 200.

Referring to FIG. 3H, fourth and fifth ones of the laminate dielectric layers 118 are formed over the interior metallization layers 120. Subsequently, openings 127 are formed in the fourth and fifth ones of the laminate dielectric layers 118, and conductive vias 122 are formed in the openings 127 in these laminate dielectric layers 118 in a similar manner as described above. Subsequently, two outer ones of the metallization layers 120 are provided on fourth and fifth ones of the laminate dielectric layers 118 and form externally accessible bond pads. Subsequently, solder resist layers 124 are formed on the outermost surfaces of the laminate dielectric layers 118.

Referring to FIG. 3I, the third semiconductor die 126 is mounted on the bond pads formed by one of the outermost metallization layers 120. As shown, the third semiconductor die 126 may be mounted in a flip-chip configuration wherein solder balls are provided between a main surface of the third semiconductor die 126 and the bond pads of the semiconductor package 100. Alternatively, the third semiconductor die 126 may be mounted according to other techniques, e.g., wire bonding, SMD (surface mount device), etc.

Referring to FIG. 4, a method for forming a semiconductor package 100 is shown, according to another embodiment. In this embodiment, the first semiconductor die 108 is arranged within the cavity 104 and is encapsulated by a first one of the laminate dielectric layers 118 that is formed within the cavity 104, and the second semiconductor die 110 is arranged outside the cavity 104 and is encapsulated by a second one of the laminate dielectric layers 118 that is formed on a lower side of the first one of the laminate dielectric layers 118 and on a lower side of the carrier frame 102 outside the cavity 104.

Referring to FIG. 4A, the carrier frame 102 is arranged on a temporary carrier 200. Subsequently, the first semiconductor die 108 is arranged on the temporary carrier 200 within the cavity 104. The first semiconductor die 108 is arranged with the main surface 112 of the first semiconductor die 108, which comprises terminals disposed thereon, facing away from the temporary carrier 200.

Referring to FIG. 4B, a lamination process is performed. In the depicted embodiment, the lamination process comprises forming a first one of the laminate dielectric layers 118 that fills the cavity 104 and encapsulates first semiconductor die 108. As shown, the first one of the laminate dielectric layers 118 may also cover an upper side of the carrier frame 102.

Referring to FIG. 4C, the second semiconductor die 110 is mounted on the first semiconductor die 108, thereby forming a chip stack 106. In this case, after forming the first one of the laminate dielectric layers 118, the temporary carrier 200 is removed, thereby exposing the rear surface 114 of the first semiconductor die 108. Subsequently, the rear surface 114 of the first semiconductor die 108 is directly attached with the rear surface 114 of the second semiconductor die 110 using the attachment material 116. This may be done by flipping the assembly comprising the first one of the laminate dielectric layers 118 encapsulating the first semiconductor die 108 upside down and placing the opposite side of the assembly on a second temporary carrier 200 (not shown).

After mounting the second semiconductor die 110 on the first semiconductor die 108, a second one of the laminate dielectric layers 118 is formed. The second one of the laminate dielectric layers 118 encapsulates the second semiconductor die 110. In this case, the second one of the laminate dielectric layers 118 is formed at the opposite side of the assembly outside of the cavity 104 and covers a lower side of the first one of the laminate dielectric layers 118 and a lower side of the carrier frame 102. The first one of the laminate dielectric layers 118 and the second one of the of the laminate dielectric layers 118 collectively form an encapsulant structure that encapsulates the first semiconductor die 108 and the second semiconductor die 110.

Referring to FIG. 4D, openings 127 are formed in the first one of the laminate dielectric layers 118 and in the second one of the laminate dielectric layers 118. The openings 127 in the first one of the laminate dielectric layers 118 include a set of openings 127 that expose the terminals from the main surface 112 of the first semiconductor die 108. The openings 127 in the second one of the laminate dielectric layers 118 include a set of openings 127 that expose the terminals from the main surface 112 of the second semiconductor die 110. Additionally, the openings 127 in the first one of the laminate dielectric layers 118 include openings 127 that expose the upper side of the metal carrier frame 102, thereby facilitating electrical contact thereto. Likewise, the openings 127 in the second one of the laminate dielectric layers 118 include openings 127 that expose the lower side of the metal carrier frame 102, thereby facilitating electrical contact thereto.

Referring to FIG. 4F, the conductive vias 122 are formed in the openings 127 in the first one of the laminate dielectric layers 118 and the second one of the laminate dielectric layers 118. This may be done by a metal deposition process, for example. Additionally, two of the metallization layers 120 are formed on the outer surfaces of the first one of the laminate dielectric layers 118 and the second one of the laminate dielectric layers 118. This may be done by a plating technique, for example. Alternatively, the metallization layers 120 can be a pre-patterned layer that is bonded to the laminate dielectric layers 118. Both sides of the package assembly may be metallized by flipping the package assembly upside on the temporary carrier 200 or by placing the package assembly on a new temporary carrier 200. Subsequently, solder resist layers 124 are formed on the outermost surfaces of the laminate dielectric layers 118.

Referring to FIG. 4G, the third semiconductor die 126 is mounted on the bond pads formed by one of the outermost metallization layers 120. As shown, the third semiconductor die 126 may be mounted in a flip-chip configuration wherein solder balls are provided between a main surface of the third semiconductor die 126 and the bond pads of the semiconductor package 100. Alternatively, the third semiconductor die 126 may be mounted according to other techniques, e.g., wire bonding, SMD (surface mount device), etc.

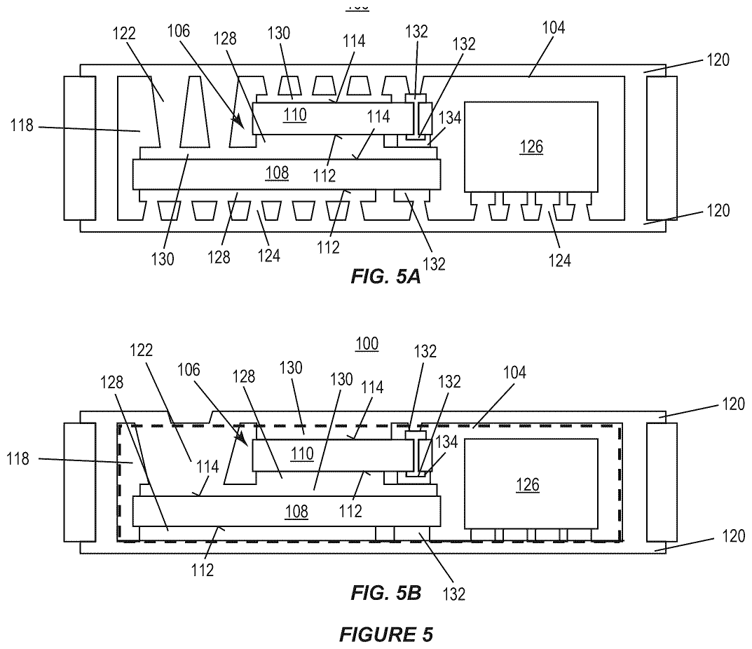

Referring to FIG. 5, a semiconductor package 100 is depicted, according to another embodiment. The semiconductor package comprises a chip stack 106 arranged within a cavity 104 of a carrier frame 102 and encapsulated by a laminate dielectric layer 118 formed within the cavity 104. In this embodiment, the first and second semiconductor dies 108, 110 are each configured as vertical devices. A vertical device refers to a device that conducts current in a vertical direction between the main surface 112 and the rear surface 114 of the respective semiconductor die. Thus, the first and second semiconductor dies 108, 110 each comprise terminals disposed on a rear surface 114 of the respective die. The chip stack 106 is configured such that a rear surface 114 terminal of the second semiconductor die 110 is mated with and directly electrically connected to a main surface 112 terminal of the first semiconductor die 108.

According to an embodiment, the first and second semiconductor dies 108, 110 are each configured as power transistor dies. That is, the first and second semiconductor dies 108, 110 may be rated to accommodate voltages of at least 100 V (volts), at least 600 V, at least 1200V or more and/or rated to accommodate currents of at least 1 A (amperes), at least 10 A, at least 50 A, at least 100 A or more. The first and second semiconductor dies 108, 110 each comprise a first load terminal 128 disposed on a main surface 112 and a second load terminal 130 disposed on a rear surface 114 of the respective semiconductor die. The first and second load terminals 130 are the voltage blocking terminals of the device, e.g., source and drain terminals in the case of a MOSFET, collector and emitter terminals in the case of an IGBT, etc. The first and second semiconductor dies 108, 110 additionally each comprise a control terminal 132 disposed on the main surface 112 of the respective semiconductor die. In the depicted embodiment, the second semiconductor die 110 is mounted on the first semiconductor die 108 such that the first load terminal 128 of the second semiconductor die 110 directly interfaces with and is electrically connected to the second load terminal 130 of the first semiconductor die 108. The first load terminal 128 of the second semiconductor die 110 may be attached and electrically connected with the second load terminal 130 of the first semiconductor die 108 by a conductive adhesive, e.g., solder, sinter, etc. Alternatively, this connection interface may be devoid of an attachment material and instead be effectuated by direct physical contact, which may be aided by applying mechanical pressure between the first and second semiconductor dies 108, 110.

In the depicted embodiment, the semiconductor package 100 comprises an insulation layer 134 disposed between the control terminal 132 of the second semiconductor die 110 and the second load terminal 130 of the first semiconductor die 108. The insulation layer 134 ensures electrical isolation of the control terminal 132 of the second semiconductor die 110 and the second load terminal 130 of the first semiconductor die 108. Generally speaking, the insulation layer 134 may be formed of and/or comprise any type of electrically insulating material, e.g., epoxy, glass, ceramic, etc. According to an embodiment, the insulation layer 134 is configured as an adhesive tape that is applied to the second load terminal 130 of the first semiconductor die 108 or the control terminal 132 of the second semiconductor die 110 prior to the mounting of the second semiconductor die 110 on the first semiconductor die 108. In the depicted embodiment, the second semiconductor die 110 comprises a second control terminal 132 disposed on the rear surface 114 of the second semiconductor die 110 that is electrically connected with the control terminal 132 on the main surface 112 of the second semiconductor die 110 by a through-via connection, i.e., a vertical connection that is internal to the semiconductor die. In this way, the control terminal 132 of the second semiconductor die 110 is available for electrical connection when the second semiconductor die 110s are arranged in a chip stack 106 configuration.

The semiconductor package 100 further comprises a third semiconductor die 126 arranged within the cavity 104 laterally adjacent to the chip stack 106. According to an embodiment, the third semiconductor die 126 is configured as an integrated circuit, e.g., a silicon-based logic device. The third semiconductor die 126 may be a driver die that is configured to control the switching operations of the first and semiconductor dies.

According to an embodiment, the semiconductor package 100 is configured as an integrated half-bridge circuit. A half-bridge circuit refers to one type of circuit topology that is used in a power conversion circuit, such as a DC-to-DC converter, DC-to-AC converter, etc. A half-bridge circuit comprises a high-side switch connected in series with a low-side switch. One load terminal of the high-side switch (e.g., the drain) is connected to a first DC voltage (e.g., a positive potential), one load terminal of the low-side switch (e.g., the source) is connected to a second DC voltage (e.g., negative potential or ground), and the remaining two load terminals (e.g., the source of the high-side switch and the drain of the low-side switch) are connected together to form the output of the half-bridge circuit. The control terminals 132 of the high-side switch and the low-side switch (e.g., the gate terminals) can be switched according to a power control scheme (e.g., pulse width modulation) to produce a desired voltage and frequency at the output of the half-bridge circuit. In an embodiment wherein the semiconductor package 100 is configured as an integrated half-bridge circuit, the second semiconductor die 110 may be the low-side switch of the half-bridge circuit, the first semiconductor die 108 may be the high-side switch of the half-bridge circuit, and the third semiconductor die 126 may be a driver die that is configured control the switching of the first and second semiconductor dies 108, 110 using a power control scheme.

The semiconductor package 100 further comprises a laminate dielectric layer 118 formed within the cavity 104. In the depicted embodiment, a single one of the laminate dielectric layers 118 encapsulates each of the first and second semiconductor dies 108, 110 and the third semiconductor die 126. More generally, any number of the laminate dielectric layers 118 may be used to encapsulate each of the first and second semiconductor dies 108, 110 and the third semiconductor die 126.

The semiconductor package 100 further comprises metallization layers 120 disposed at the outside of the package. These metallization layers 120 form externally accessible bond pads of the semiconductor package 100 and may form electrical routings.

The semiconductor package 100 further comprises conductive vias 122 provide vertical electrical interconnect between the metallization layers 120 and the terminals of the first, second and third semiconductor dies 108, 110, 126. In the embodiment of FIG. 5A, the semiconductor package 100 comprises so-called buried vias that form direct connections between the metallization layers 120 and the terminals from one of the first, second and third semiconductor dies 108, 110, 126. The vias may be formed in trenches that are formed in the laminate dielectric layers 118. Additionally, the carrier frame 102 itself is configured as a vertical through-via that provides an electrical connection between opposing sides of the semiconductor package 100. In the embodiment of FIG. 5B, the semiconductor package 100 is formed without the so-called buried vias. Instead, the terminals of the first, second and third semiconductor dies 108, 110, 126 are exposed and directly contacted by metallization layers 120 formed thereon.

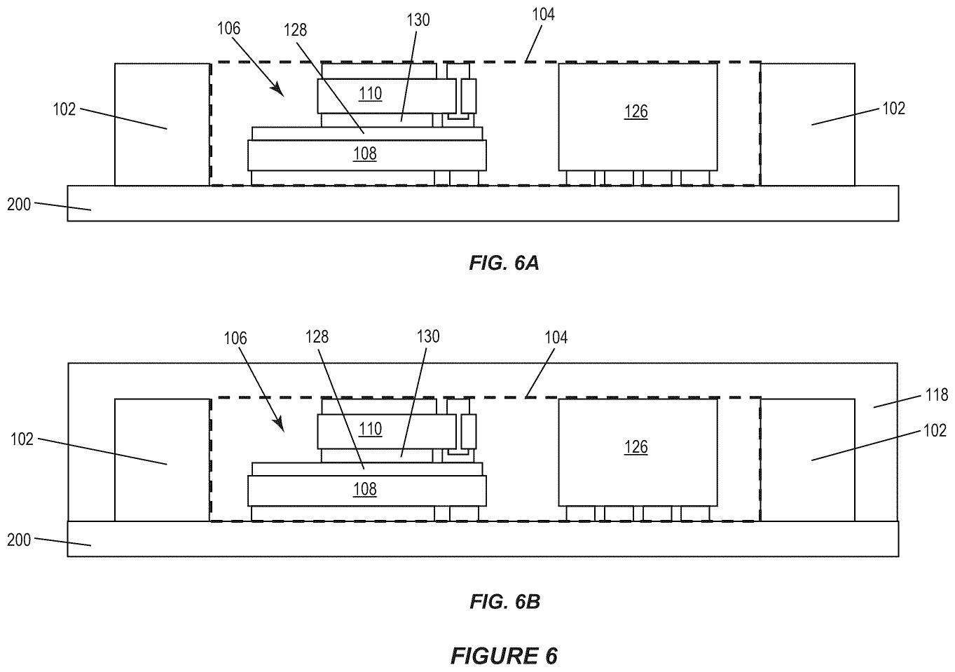

Referring to FIG. 6, a method for forming the semiconductor package 100 is shown, according to an embodiment.

Referring to FIG. 6A, the carrier frame 102 is arranged on a temporary carrier 200. Subsequently, the chip stack 106 comprising the first and second semiconductor dies 108, 110 is arranged on the temporary carrier 200 within the cavity 104, and the third semiconductor die 126 is mounted on the temporary carrier 200 within the cavity 104 laterally adjacent to the chip stack 106. As mentioned above, the chip stack 106 may be formed by providing an electrically conductive adhesive between the first load terminal 128 of the first semiconductor die 108 and the second load terminal 130 of the second semiconductor die 110 e.g., solder, sinter, etc. Alternatively, the chip stack 106 may be formed by mechanically pressing the first load terminal 128 of the first semiconductor die 108 and the second load terminal 130 of the second semiconductor die 110 together.

Referring to FIG. 6B, a lamination process is performed. In the depicted embodiment, a single laminate dielectric layer 118 is formed that fills the cavity 104 and encapsulates the chip stack 106 and the third semiconductor die 126 that is laterally adjacent to the chip stack 106. As shown, the laminate dielectric layer 118 may be formed to cover the carrier frame 102. After performing the lamination process, further processing steps may be performed to form the metallization layers 120 and the conductive vias 122 of the semiconductor package 100. These further processing steps may be performed according to any of the methods described above.

The semiconductor package described herein may comprise one or more semiconductor dies with a variety of different configurations. These semiconductor dies may be singulated from a semiconductor wafer (not shown), e.g. by sawing, prior to package production. In general, the semiconductor wafer and therefore the resulting semiconductor die may be made of any semiconductor material suitable for manufacturing a semiconductor device. Examples of such materials include, but are not limited to, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc. In general, the semiconductor die can be any active or passive electronic component. Examples of these devices include power semiconductor devices, such as power MISFETs (Metal Insulator Semiconductor Field Effect Transistors) power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), power bipolar transistors or power diodes such as, e.g., PIN diodes or Schottky diodes, etc. Other examples of these devices include logic devices, such as microcontrollers, processors, field programmable gate arrays (FPGAs), memory circuits, level shifters, sensor devices, etc. One or more of the semiconductor dies can be configured as a so-called lateral device. In this configuration, the terminals of the semiconductor die are provided on a single main surface and the semiconductor die is configured to conduct in a direction that is parallel to the main surface of the semiconductor die. Alternatively, one or more of the semiconductor dies can be configured as a so-called vertical device. In this configuration, the terminals of the semiconductor die are provided on opposite facing main and rear surface 114s and the semiconductor die is configured to conduct in a direction that is perpendicular to the main surface of the semiconductor die.

The semiconductor package described herein may be a so-called “chip-embedded” package. A chip-embedded package comprises an encapsulant body formed from multiple constituent layers of dielectric material that are laminated (stacked) on top of one another. This package type differs from a molded package wherein the encapsulant body is provided by a monolithic region of electrically insulating material, such as a mold compound that encapsulates the semiconductor die and associated electrical connectors, e.g., bond wires, clips, etc. In a chip-embedded package, each constituent laminate layer can generally comprise any dielectric material that is suitable for semiconductor device encapsulation. Examples of these dielectric materials include epoxy materials, blended epoxy and glass fiber materials such as FR-4, FR-5, CEM-4, etc., and resin materials such as bismaleimide trazine (BT) resin. A chip-embedded package may also include multiple layers of metallization, e.g., copper, aluminum, etc., and alloys thereof, formed on top of at least some of the constituent laminate layers. These layers of metallization can be structured to form internal interconnect lines within the package body as well as the bond pads that are exposed at the outer surfaces of the package body. Due to the electrical interconnect provided by the internal structured metallization, a chip-embedded package does not require a lead frame or electrical connectors such as bond wires or clips. Therefore, the semiconductor package may be devoid of a die pad that accommodates the semiconductor dies and/or devoid of conductive leads that are formed from the same lead frame structure as a die pad.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Although the present disclosure is not so limited, the following numbered examples demonstrate one or more aspects of the disclosure.

Example 1. A method of producing a semiconductor package, the method comprising: providing a first semiconductor die and a second semiconductor die; providing a carrier frame comprising a cavity; mounting the second semiconductor die on the first semiconductor die, thereby forming a chip stack; and forming one or more laminate dielectric layers within the cavity that encapsulate at least one of the second semiconductor die and the first semiconductor die.

Example 2. The method of example 1, wherein mounting the second semiconductor die on the first semiconductor die comprises applying an attachment material between the first semiconductor die and the second semiconductor die, wherein the attachment material has a different composition as the one or more laminate dielectric layers.

Example 3. The method of example 2, wherein the first and second semiconductor dies each comprise a main surface comprising one or more terminals disposed thereon and a rear surface opposite from the main surface, and wherein applying the attachment material comprises directly adhering the rear surface of the first semiconductor die with the rear surface of the second semiconductor die using the attachment material.

Example 4. The method of example 2, wherein the second semiconductor die is mounted on the first semiconductor die before forming any of the dielectric layers that are formed within the cavity.

Example 5. The method of example 4, wherein the method comprises: arranging the carrier frame on a temporary carrier; arranging the chip stack on the temporary carrier and within the cavity; and forming a first one of the laminate dielectric layers that covers both of the first semiconductor die and the second semiconductor die after mounting the second semiconductor die on the first semiconductor die.

Example 6. The method of example 2, wherein at least one of the laminate dielectric layers is formed within the cavity before mounting the second semiconductor die on the first semiconductor die.

Example 7. The method of example 6, wherein the method comprises: arranging the carrier frame on a temporary carrier; arranging the first semiconductor die on the temporary carrier and within the cavity; forming a first one of the laminate dielectric layers that encapsulates the first semiconductor die; forming an opening in the first one of the laminate dielectric layers so as to expose the first semiconductor die; and mounting the second semiconductor die on the first semiconductor die, thereby forming the chip stack within the cavity; and forming a second one of the laminate dielectric layers that encapsulates the second semiconductor die.

Example 8. The method of example 6, wherein the method comprises: arranging the carrier frame on a temporary carrier; arranging the first semiconductor die on the temporary carrier and within the cavity; forming a first one of the laminate dielectric layers that encapsulates the first semiconductor die; removing the temporary carrier from a rear side of the first semiconductor die and the carrier frame; mounting the second semiconductor die on the first semiconductor die by attaching a rear side of the second semiconductor die with a rear side of the first semiconductor die, thereby forming the chip stack; and forming a second one of the laminate dielectric layers on a lower side of the first one of the laminate dielectric layers and on a lower side of the carrier frame such that the second semiconductor die is encapsulated by the second one of the laminate dielectric layers.

Example 9. The method of example 1, further comprising: forming bond pads at an outer side of the one or more laminate dielectric layers; forming conductive vias that form electrical connections between the bond pads and one or both of the first and second semiconductor dies; and mounting a third semiconductor die on the outer side and of the one or more laminate dielectric layers and electrically connected with the bond pads.

Example 10. A method of producing a semiconductor package, the method comprising: providing a first power transistor die and a second power transistor die, the first and second power transistor dies each comprising a first load terminal disposed on a main surface and a second load terminal disposed on a rear surface opposite from the main surface; providing a carrier frame comprising a cavity; mounting the second power transistor die on the first power transistor die such that the first load terminal of the first power transistor die directly interfaces with and is electrically connected to the second load terminal of the second power transistor die, thereby forming a chip stack; arranging the chip stack within the cavity; and forming one or more laminate dielectric layers within the cavity that encapsulate the chip stack.

Example 11. The method of example 10, further comprising: providing a third semiconductor die within the cavity laterally adjacent to the chip stack, and wherein the third semiconductor die is encapsulated by the one or more laminate dielectric layers.

Example 12. The method of example 11, wherein the first and second power transistor dies are configured as a half-bridge circuit, and wherein the third semiconductor die is a logic device that is configured to control a switching operation of the half-bridge circuit.

Example 13. The method of example 10, wherein the first and second power transistor dies each comprise a control terminal disposed on the main surface, wherein the second power transistor die comprises a second control terminal disposed on the rear surface of the second power transistor die, the second control terminal being electrically connected with the control terminal of the second semiconductor power by a through-via connection, and wherein the method further comprises providing an insulation layer between the second control terminal of the second power transistor die and the second load terminal of the first power transistor die.

Example 14. A semiconductor package, comprising: a carrier frame comprising a cavity; a chip stack comprising a second semiconductor die mounted directly on a first semiconductor die; and one or more laminate dielectric layers formed within the cavity, wherein at least one of the second semiconductor die and the first semiconductor die is arranged within the cavity and is encapsulated by the one or more laminate dielectric layers.

Example 15. The semiconductor package of example 14, further comprising an attachment material between the first semiconductor die and the second semiconductor die, wherein the attachment material has a different composition as the one or more laminate dielectric layers.

Example 16. The semiconductor package of example 15, wherein the first and second semiconductor dies each comprise a main surface comprising one or more terminals disposed thereon and a rear surface opposite from the main surface, and wherein the attachment material forms a direct interface between the rear surface of the first semiconductor die and the rear surface of the second semiconductor die.

Example 17. The semiconductor package of example 14, wherein both of the second semiconductor die and the first semiconductor die are arranged within the cavity and are encapsulated by the one or more laminate dielectric layers.

Example 18. The semiconductor package of example 17, wherein both of the second semiconductor die and the first semiconductor die are encapsulated by a first one of the laminate dielectric layers.

Example 19. The semiconductor package of example 17, wherein the first semiconductor die is encapsulated by a first one of the laminate dielectric layers, and wherein the second semiconductor die is encapsulated by a second one of the laminate dielectric layers.

Example 20. The semiconductor package of example 14, wherein the first semiconductor is arranged within the cavity and is encapsulated by a first one of the laminate dielectric layers that is formed within the cavity, and wherein the second semiconductor die is arranged outside the cavity and is encapsulated by a second one of the laminate dielectric layers that is formed on a lower side of the first one of the laminate dielectric layers and on a lower side of the carrier frame.

Example 21. The semiconductor package of example 14, further comprising: bond pads disposed at an outer side of the one or more laminate dielectric layers; conductive vias that form electrical connections between the bond pads and one or both of the first and second semiconductor dies; and a third semiconductor die mounted on the outer side and electrically connected with the bond pads.

Example 22. A semiconductor package, comprising: a carrier frame comprising a cavity; a chip stack arranged within the cavity and comprising a first power transistor die and a second power transistor die, the first and second power transistor dies each comprising a first load terminal disposed on a main surface and a second load terminal disposed on a rear surface opposite from the main surface; and one or more laminate dielectric layers formed within the cavity, wherein the second power transistor die is mounted on the first power transistor die such that the first load terminal of the first power transistor die directly interfaces with and is electrically connected to the second load terminal of the second power transistor die, and wherein the chip stack is encapsulated by the one or more laminate dielectric layers.

Example 23. The semiconductor package of example 22, further comprising a third semiconductor die, wherein the third semiconductor die is encapsulated by the one or more laminate dielectric layers within the cavity that encapsulate the chip stack.

Example 24. The semiconductor package of example 23, wherein the first and second power transistor dies are configured as a half-bridge circuit, and wherein the third semiconductor die is a logic device that is configured to control a switching operation of the half-bridge circuit.

Example 25. The semiconductor package of example 22, wherein the first and second power transistor dies each comprise a control terminal disposed on the main surface, wherein the second power transistor die comprises a second control terminal disposed on the rear surface of the second power transistor die, the second control terminal being electrically connected with the control terminal of the second semiconductor power by a through-via connection, and wherein the semiconductor package further comprises an insulation layer between the second control terminal of the second power transistor die and the second load terminal of the first power transistor die.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of producing a semiconductor package, the method comprising:
providing a first semiconductor die and a second semiconductor die;
providing a carrier frame comprising a cavity;
mounting the second semiconductor die on the first semiconductor die, thereby forming a chip stack; and
forming one or more laminate dielectric layers within the cavity that encapsulate at least one of the second semiconductor die and the first semiconductor die.

2. The method of claim 1, wherein mounting the second semiconductor die on the first semiconductor die comprises applying an attachment material between the first semiconductor die and the second semiconductor die, wherein the attachment material has a different composition as the one or more laminate dielectric layers.

3. The method of claim 2, wherein the first and second semiconductor dies each comprise a main surface comprising one or more terminals disposed thereon and a rear surface opposite from the main surface, and wherein applying the attachment material comprises directly adhering the rear surface of the first semiconductor die with the rear surface of the second semiconductor die using the attachment material.

4. The method of claim 2, wherein the second semiconductor die is mounted on the first semiconductor die before forming any of the dielectric layers that are formed within the cavity.

5. The method of claim 4, wherein the method comprises:
arranging the carrier frame on a temporary carrier;
arranging the chip stack on the temporary carrier and within the cavity; and
forming a first one of the laminate dielectric layers that covers both of the first semiconductor die and the second semiconductor die after mounting the second semiconductor die on the first semiconductor die.

6. The method of claim 2, wherein at least one of the laminate dielectric layers is formed within the cavity before mounting the second semiconductor die on the first semiconductor die.

7. The method of claim 6, wherein the method comprises:
arranging the carrier frame on a temporary carrier;
arranging the first semiconductor die on the temporary carrier and within the cavity;
forming a first one of the laminate dielectric layers that encapsulates the first semiconductor die;
forming an opening in the first one of the laminate dielectric layers so as to expose the first semiconductor die; and
mounting the second semiconductor die on the first semiconductor die, thereby forming the chip stack within the cavity; and
forming a second one of the laminate dielectric layers that encapsulates the second semiconductor die.

8. The method of claim 6, wherein the method comprises:
arranging the carrier frame on a temporary carrier;
arranging the first semiconductor die on the temporary carrier and within the cavity;
forming a first one of the laminate dielectric layers that encapsulates the first semiconductor die;
removing the temporary carrier from a rear side of the first semiconductor die and the carrier frame;
mounting the second semiconductor die on the first semiconductor die by attaching a rear side of the second semiconductor die with a rear side of the first semiconductor die, thereby forming the chip stack; and
forming a second one of the laminate dielectric layers on a lower side of the first one of the laminate dielectric layers and on a lower side of the carrier frame such that the second semiconductor die is encapsulated by the second one of the laminate dielectric layers.

9. The method of claim 1, further comprising:
forming bond pads at an outer side of the one or more laminate dielectric layers;
forming conductive vias that form electrical connections between the bond pads and one or both of the first and second semiconductor dies; and
mounting a third semiconductor die on the outer side and of the one or more laminate dielectric layers and electrically connected with the bond pads.

10. A method of producing a semiconductor package, the method comprising:
providing a first power transistor die and a second power transistor die, the first and second power transistor dies each comprising a first load terminal disposed on a main surface and a second load terminal disposed on a rear surface opposite from the main surface;
providing a carrier frame comprising a cavity;
mounting the second power transistor die on the first power transistor die such that the first load terminal of the first power transistor die directly interfaces with and is electrically connected to the second load terminal of the power transistor die, thereby forming a chip stack;
arranging the chip stack within the cavity; and
forming one or more laminate dielectric layers within the cavity that encapsulate the chip stack.

11. The method of claim 10, further comprising:
providing a third semiconductor die within the cavity laterally adjacent to the chip stack, and
wherein the third semiconductor die is encapsulated by the one or more laminate dielectric layers.

12. The method of claim 11, wherein the first and second power transistor dies are configured as a half-bridge circuit, and wherein the third semiconductor die is a logic device that is configured to control a switching operation of the half-bridge circuit.

13. The method of claim 10, wherein the first and second power transistor dies each comprise a control terminal disposed on the main surface, wherein the second power transistor die comprises a second control terminal disposed on the rear surface of the second power transistor die, the second control terminal being electrically connected with the control terminal of the second power transistor die by a through-via connection, and wherein the method further comprises providing an insulation layer between the second control terminal of the second power transistor die and the second load terminal of the first power transistor die.

14. A semiconductor package, comprising:
a carrier frame comprising a cavity;
a chip stack comprising a second semiconductor die mounted directly on a first semiconductor die; and
one or more laminate dielectric layers formed within the cavity,
wherein at least one of the second semiconductor die and the first semiconductor die is arranged within the cavity and is encapsulated by the one or more laminate dielectric layers.

15. The semiconductor package of claim 14, further comprising an attachment material between the first semiconductor die and the second semiconductor die, wherein the attachment material has a different composition as the one or more laminate dielectric layers.

16. The semiconductor package of claim 15, wherein the first and second semiconductor dies each comprise a main surface comprising one or more terminals disposed thereon and a rear surface opposite from the main surface, and wherein the attachment material forms a direct interface between the rear surface of the first semiconductor die and the rear surface of the second semiconductor die.

17. The semiconductor package of claim 14, wherein both of the second semiconductor die and the first semiconductor die are arranged within the cavity and are encapsulated by the one or more laminate dielectric layers.

18. The semiconductor package of claim 17, wherein both of the second semiconductor die and the first semiconductor die are encapsulated by a first one of the laminate dielectric layers.

19. The semiconductor package of claim 17, wherein the first semiconductor die is encapsulated by a first one of the laminate dielectric layers, and wherein the second semiconductor die is encapsulated by a second one of the laminate dielectric layers.

20. The semiconductor package of claim 14, wherein the first semiconductor is arranged within the cavity and is encapsulated by a first one of the laminate dielectric layers that is formed within the cavity, and wherein the second semiconductor die is arranged outside the cavity and is encapsulated by a second one of the laminate dielectric layers that is formed on a lower side of the first one of the laminate dielectric layers and on a lower side of the carrier frame.

21. The semiconductor package of claim 14, further comprising:
bond pads disposed at an outer side of the one or more laminate dielectric layers;
conductive vias that form electrical connections between the bond pads and one or both of the first and second semiconductor dies; and
a third semiconductor die mounted on the outer side and electrically connected with the bond pads.

22. A semiconductor package, comprising:
a carrier frame comprising a cavity;
a chip stack arranged within the cavity and comprising a first power transistor die and a second power transistor die, the first and second power transistor dies each comprising a first load terminal disposed on a main surface and a second load terminal disposed on a rear surface opposite from the main surface; and
one or more laminate dielectric layers formed within the cavity,
wherein the second power transistor die is mounted on the first power transistor die such that the first load terminal of the first power transistor die directly interfaces with and is electrically connected to the second load terminal of the second power transistor die, and
wherein the chip stack is encapsulated by the one or more laminate dielectric layers.

23. The semiconductor package of claim 22, further comprising a third semiconductor die, wherein the third semiconductor die is encapsulated by the one or more laminate dielectric layers within the cavity that encapsulate the chip stack.

24. The semiconductor package of claim 23, wherein the first and second power transistor dies are configured as a half-bridge circuit, and wherein the third semiconductor die is a logic device that is configured to control a switching operation of the half-bridge circuit.

25. The semiconductor package of claim 22, wherein the first and second power transistor dies each comprise a control terminal disposed on the main surface, wherein the second power transistor die comprises a second control terminal disposed on the rear surface of the second power transistor die, the second control terminal being electrically connected with the control terminal of the second semiconductor power by a through-via connection, and wherein the semiconductor package further comprises an insulation layer between the second control terminal of the second power transistor die and the second load terminal of the first power transistor die.
